(19) United States
(12) Patent Application Publication
(10) Pub. No.: US 2024/0386171 A1
(43) Pub. Date: Nov. 21, 2024

(54) FASTER EVALUATION OF BOOLEAN CIRCUITS IN LIMITED COMPUTATIONAL ENVIRONMENTS

(71) Applicant: International Business Machines Corporation, Armonk, NY (US)

(72) Inventors: Nir Drucker, Zichron Yaakov (IL); Eyal Kushnir, Kfar Vradim (IL); Ariel Farkash, Shimshit (IL)

(21) Appl. No.: 18/197,745

(22) Filed: May 16, 2023

(51) Int. Cl. G06F 9/30

(52) U.S. Cl. CPC G06F 30/32; G06F 7/544; G06F 7/724; G06F 17/10; G06F 30/33

(57) ABSTRACT

A computer-implemented method comprising: receiving a Boolean circuit embodied in a digital file and input variables associated with the Boolean circuit; analyzing a structure of the Boolean circuit to identify a pattern of Boolean operations comprising one or more chains of XOR operations over groups of four of the input variables; automatically evaluating each of the one or more chains of XOR operations over the groups of four input variables, using a defined logical gate XOR_{T} which replaces at least some required multiplication operations with complex conjugate operations; and automatically calculating any identified AND operations performed on adjacent XORed pairs in the Boolean circuit, using defined pseudo logical gates AND_{P} and XOR_{P}.

### BACKGROUND

The invention relates to the field of homomorphic encryption, and, specifically, to the field of Boolean circuit evaluation within computational environments that support a limited set of operations.

In the field of computer science, a Boolean circuit is often defined as a mathematical model for combinational digital logic circuits. Boolean circuits are defined in terms of the logic gates they contain, such as AND, OR, NAND, NOR, XOR, and XNOR gates. Each gate executes some Boolean function that takes a fixed number of bits as input and outputs a single bit.

The Circuit Evaluation Problem (or Circuit Value Problem) is the computational problem of computing (evaluating) the output of a Boolean circuit, given certain input. Various software products exist for Boolean circuit evaluation.

Evaluating a Boolean circuit's output is useful not only for designing and simulating electronic circuits, but also for executing certain software algorithms by first converting or compiling them into Boolean circuits, and then evaluating the outputs of these circuits given certain inputs.

Certain computational environments support only a limited set of arithmetic operations, for example, only additions and multiplications, and thus cannot natively evaluate Boolean circuits. To evaluate a Boolean circuit in such a limited environment, the circuit's Boolean operations must be simulated by the supported arithmetic operations (i.e., additions and/or multiplications). This simulation often means that a discrete Boolean operation must be expressed by a sequence of arithmetic operations, leading to increased computational complexity and computation time.

One example of such limited computational environment is certain Homomorphic Encryption (HE) schemes, which use computations over the complex plane. HE is a cryptographic technique that allows computations to be made on encrypted data (ciphertext) without first decrypting it. Under a homomorphic encryption scheme, these computations will yield the same results, when decrypted, as if they were performed on the data in its unencrypted form (plaintext).

In the context of Boolean circuit evaluation, HE is often used for encrypting the inputs to the circuit, executing the simulated Boolean operations on the encrypted inputs, outputting an encrypted result, and then deciphering the result to obtain a plaintext output. The evaluation of the circuit (namely, the execution of the Boolean operations to generate the encrypted output) may be performed at a certain computerized device (e.g., a server), and the encryption and decryption may be performed on a different computerized device (e.g., a client), by a user who does not wish for the server to be exposed to unencrypted inputs and outputs of the circuit.

In this scenario, the server is only exposed to the unencrypted circuit and cannot decrypt the input and output. This separation between encryption/decryption and computation makes HE particularly useful when computation of personal or sensitive data has to be outsourced to an entity or location where their secrecy cannot be guaranteed, such as a cloud environment. Such personal or sensitive data can be first encrypted using HE, and then transmitted (for example, to commercial cloud environment) for processing, all while encrypted. The results of the computations, still in an encrypted form, are then provided back to the original sender, who can decrypt them in a safe environment and observe the results. This procedure diminishes privacy and other secrecy concerns, as the unencrypted data is never made available to the entity performing the computations, and naturally also not to any malicious third party who manages to compromise that entity's computer storage or intercept the transmissions between that entity and the original sender.

Because HE operations on encrypted data are far more complex than equivalent operations performed on unencrypted data, evaluating a Boolean circuit using a HE scheme is generally more complex and lengthy than evaluation done on unencrypted data.

The foregoing examples of the related art and limitations related therewith are intended to be illustrative and not exclusive. Other limitations of the related art will become apparent to those of skill in the art upon a reading of the specification and a study of the figures.

### SUMMARY

The following embodiments and aspects thereof are described and illustrated in conjunction with systems, tools and methods which are meant to be exemplary and illustrative, not limiting in scope.

One embodiment relates to a computer-implemented method comprising: receiving a Boolean circuit embodied in a digital file and input variables associated with the Boolean circuit; analyzing a structure of the Boolean circuit to identify a pattern of Boolean operations comprising one or more chains of XOR operations over groups of four of the input variables; automatically evaluating each of the one or more chains of XOR operations over the groups of four input variables, using a defined logical gate XOR_{T} which replaces at least some required multiplication operations with complex conjugate operations; and automatically calculating any identified AND operations performed on adjacent XORed pairs in the Boolean circuit, using defined pseudo logical gates AND_{P} and XOR_{P}.

Another embodiment relates to a system comprising at least one hardware processor; and a non-transitory computer-readable storage medium having program code embodied therewith, the program code executable by the at least one hardware processor to: receive a Boolean circuit embodied in a digital file and input variables associated with the Boolean circuit, analyze a structure of the Boolean circuit to identify a pattern of Boolean operations comprising one or more chains of XOR operations over groups of four of the input variables, automatically evaluate each of the one or more chains of XOR operations over the groups of four input variables, using a defined logical gate XOR_{T} which replaces at least some required multiplication operations with complex conjugate operations, and automatically calculate any identified AND operations performed on adjacent XORed pairs in the Boolean circuit, using defined pseudo logical gates AND_{P} and XOR_{P}.

A further embodiment relates to a computer program product comprising a non-transitory computer-readable storage medium having program code embodied therewith, the program code executable by at least one hardware processor to: receive a Boolean circuit embodied in a digital file and input variables associated with the Boolean circuit, analyze a structure of the Boolean circuit to identify a pattern of Boolean operations comprising one or more chains of XOR operations over groups of four of the input variables, automatically evaluate each of the one or more chains of XOR operations over the groups of four input variables, using a defined logical gate XOR_{T} which replaces at least some required multiplication operations with complex conjugate operations, and automatically calculate any identified AND operations performed on adjacent XORed pairs in the Boolean circuit, using defined pseudo logical gates AND_{P} and XOR_{P}.

In some embodiments, the method further comprises, and the program code is further executable to, repeat the analyzing over a result of the evaluating and calculating, to identify, in the result, a next pattern of Boolean operations comprising one or more chains of XOR operations over new groups of four input variables; and perform the evaluating and the calculating over the next pattern.

In some embodiments, the (i) evaluating is performed, with respect to each of the groups of four input variables, by applying a combined logical gate XOR_{P,T}, such that x XOR_{P,T} y=(x−y), wherein x, y∈{0,0.5}; and (ii) the calculating is performed, with respect to each adjacent XORed pairs, by applying a combined logical gate AND_{P,T}, such that x AND_{P,T} y=2xy, wherein x, y∈{−0.5,0,0.5}.

In some embodiments, the logical gate XOR_{T} is defined such that x XOR_{T} y=2(x−y)², wherein x, y∈{0,0.5}.

In, the evaluating is performed by executing an addition operation between pairs of consecutive the input variables, wherein in each of the pairs, an even-indexed variable is multiplied by the unit imaginary number i=\sqrt{−1};

In some embodiments, (i) the pseudo logical gate AND_{P} is defined such that x AND_{P} y=xy, wherein x, y∈{−1,0,1}; and (ii) the pseudo logical gate XOR_{P} is defined such that x XOR_{P} y=(x−y), wherein x, y∈{0,1}.

In some embodiments, the evaluating is performed in a computational environment which supports a limited set of arithmetic operations.

In some embodiments, the limited set of arithmetic operations include additions, multiplications, and conjugations.

In some embodiments, the computational environment is an approximate Homomorphic Encryption (HE) scheme environment, and wherein the input variables and the evaluation results are encrypted.

In addition to the exemplary aspects and embodiments described above, further aspects and embodiments will become apparent by reference to the figures and by study of the following detailed description.

### BRIEF DESCRIPTION OF THE FIGURES

Exemplary embodiments are illustrated in referenced figures. Dimensions of components and features shown in the figures are generally chosen for convenience and clarity of presentation and are not necessarily shown to scale. The figures are listed below.

FIG. 1 is a block diagram of an exemplary system for performing the inventive methods, according to an embodiment.

FIG. 2A is a flowchart of a method for evaluating a Boolean circuit comprising a series of AND operations of multiple XOR results, according to an embodiment.

FIG. 2B is a flowchart of a method for evaluating a Boolean circuit comprising exclusive disjunction (XOR) over four input variables x₁, x₂, x₃, x₄, or any multiple of four variables, according to an embodiment.

FIG. 2C illustrates a method for evaluating an input Boolean circuit comprising chains of XOR operations over four input variables x₁, x₂, x₃, x₄, with conjugation operations of adjacent XORed pairs, according to an embodiment.

FIG. 2D illustrates a method for evaluating an input Boolean circuit comprising chains of XOR operations over four input variables x₁, x₂, x₃, x₄, with conjugation operations of adjacent XORed pairs, according to an embodiment.

### DETAILED DESCRIPTION

Disclosed herein are a system, computer-implemented method, and computer program product, for performing faster evaluation of Boolean circuits within computational environments that support only a limited set of operations, such as only additions and multiplications.

As noted above, one example of such a limited computational environment is approximate Homomorphic Encryption (HE) schemes, such as CKKS (see, Jung Hee Cheon, et al. Homomorphic Encryption for Arithmetic. In ASIACRYPT 2017, Part I, LNCS 10624, pp. 409-437, 2017), which use computations over the complex plane, and cannot natively handle binary circuits. Accordingly, in order to enable evaluation of Boolean circuits in an approximate HE environment, it is necessary to use arithmetic computations to simulate the Boolean functions contained in the circuit.

Table 1 below illustrates some examples of arithmetic computations used to compute common Boolean functions. As can be seen, common binary functions, such as logical conjunction (AND), logical disjunction (OR), or logical exclusive disjunction (XOR), require at least one multiplication operation. In practice there are two factors that may be considered—the number of multiplications, and the multiplicative depth of the circuit. By way of explanation, each homomorphic operation applied on ciphertexts increases a noise component in the result. Typically, the noise growth induced by multiplication operations is greater than the noise growth induced by addition. After a predefined number of homomorphic operations, the noise component becomes too large to guarantee correct decryption of the result, and a bootstrap operation is required to clean up the growing noise. Because bootstrap operations are costly from a computational perspective, reducing the multiplicative depth of Boolean circuits to be evaluated in a given HE scheme will optimize the evaluation process.

The number of multiplications required to simulate an entire binary circuit, comprising multiple functions, will determine the computational overhead and, ultimately, the overall latency of the computation.

TABLE 1

| Binary Function | Arithmetic Equivalent |
|---|---|
| x∧y = xy | 1 multiplication |
| x ∨ y = x + y − xy | 1 multiplication, 2 additions |
| x ⊕ y = (x − y)² | 1 multiplication, 1 addition |

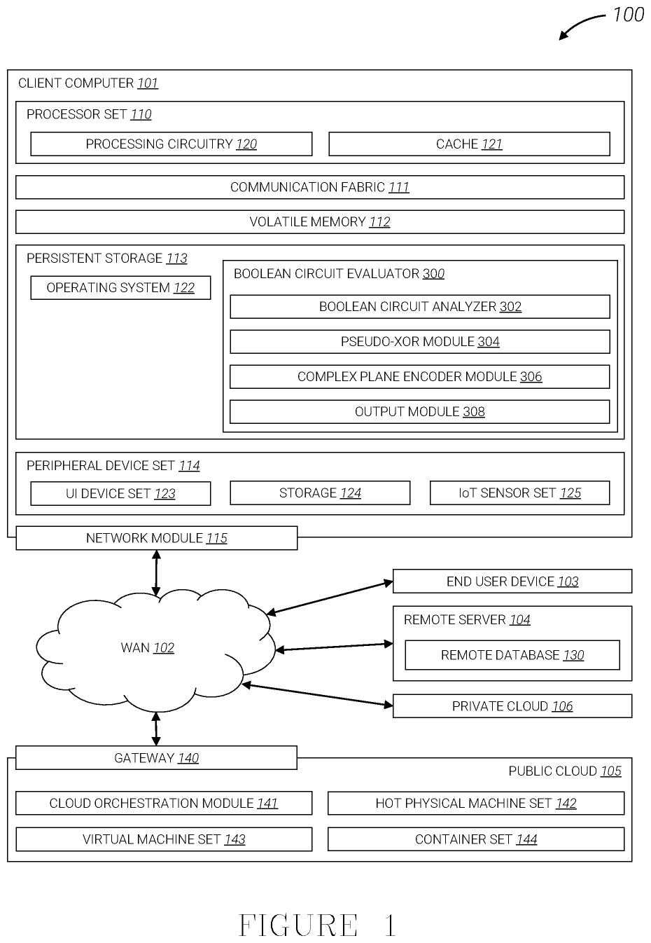

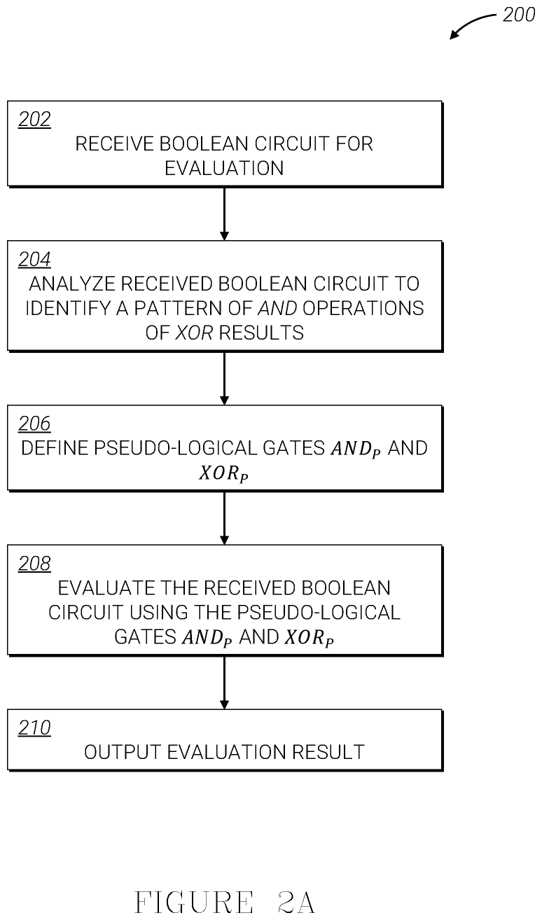

Reference is now made to FIG. 1, which shows a block diagram of an exemplary computing environment 100, containing an example of an environment for the execution of at least some of the computer code involved in performing the inventive methods, such as Boolean circuit evaluator 300, comprising one or more modules, such as Boolean circuit analyzer 302, pseudo-XOR module 304, complex plane encoder 306, and/or output module 308. In addition to Boolean circuit evaluator 300, computing environment 100 includes, for example, a computer 101, a wide area network (WAN) 102, an end user device (EUD) 103, a remote server 104, a public cloud 105, and/or a private cloud 106. In this example, computer 101 includes a processor set 110 (including processing circuitry 120 and a cache 121), a communication fabric 111, a volatile memory 112, a persistent storage 113 (including an operating system 122 and Boolean circuit evaluator 300, as identified above), a peripheral device set 114 (including a user interface (UI), a device set 123, a storage 124, and an Internet of Things (IoT) sensor set 125), and a network module 115. Remote server 104 includes a remote database 130. Public cloud 105 includes a gateway 140, a cloud orchestration module 141, a host physical machine set 142, a virtual machine set 143, and a container set 144.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network and/or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one or more computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the method(s) specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in Boolean circuit evaluator 300 in persistent storage 113.

Communication fabric 111 is the signal conduction paths that allow the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, the volatile memory is characterized by random access, but this is not required unless affirmatively indicated. In computer 101, volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read-only memory (ROM), but typically at least a portion of the persistent storage allows writing of data, deletion of data and re-writing of data. Some familiar forms of persistent storage include magnetic disks and solid-state storage devices. Operating system 122 may take several forms, such as various known proprietary operating systems or open source Portable Operating System Interface type operating systems that employ a kernel. The code included in Boolean circuit evaluator 300 typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the Internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as a network interrace controller (NIC), a modem, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through the hardware included in network module 115.

WAN 102 is any wide area network (for example, the Internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the Internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

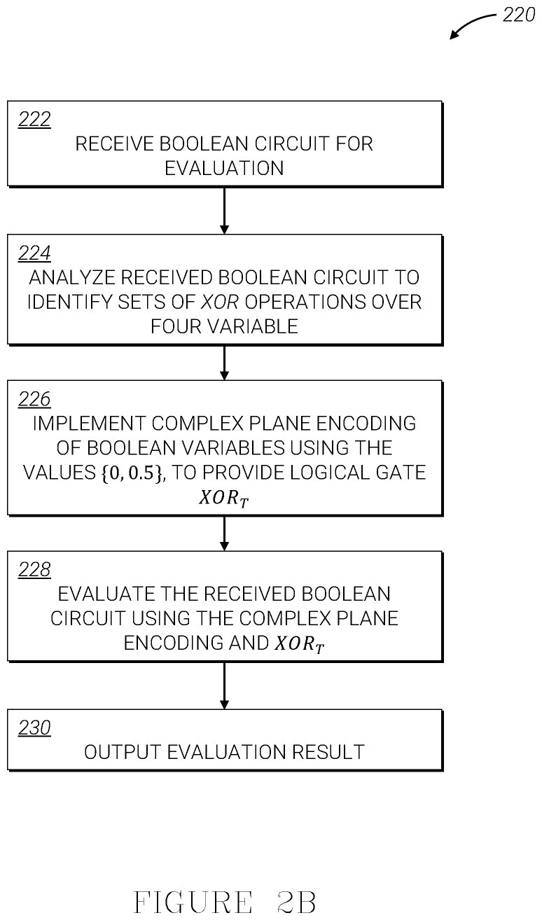

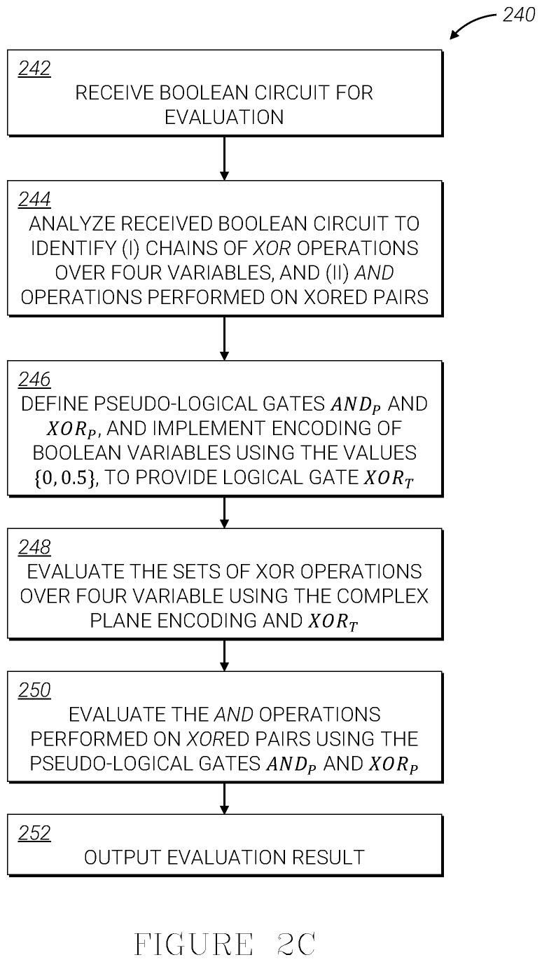

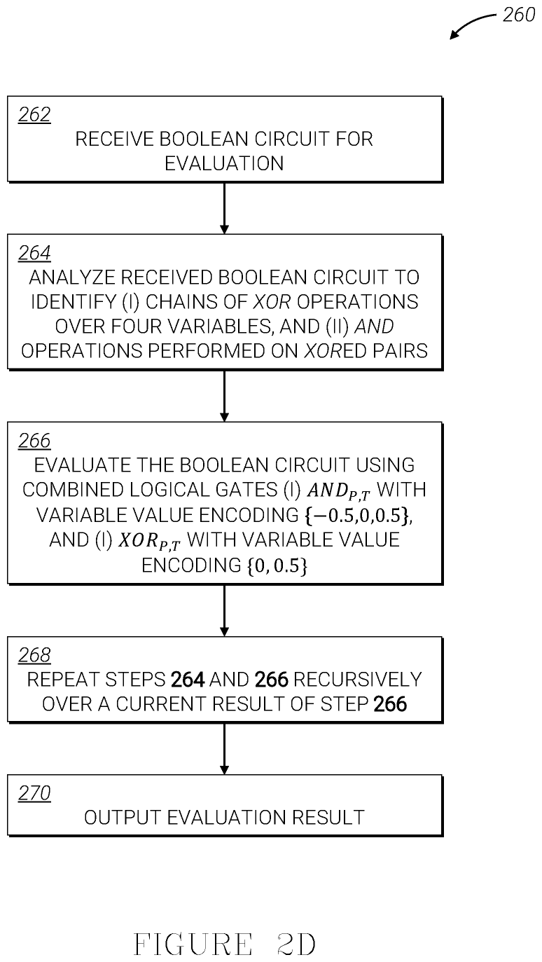

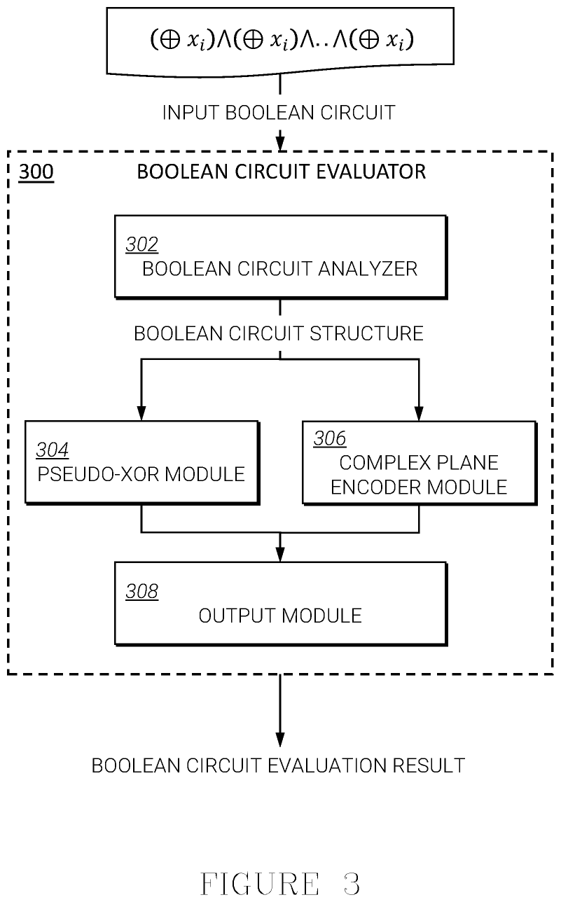

The instructions of Boolean circuit evaluator 300 are now discussed with reference to the flowchart of FIG. 2A, which illustrates a method 200 for evaluating a Boolean circuit comprising a series of AND operations of multiple XOR results, within the context of a computational environment that supports only a limited set of arithmetic operation, such as only additions and multiplications. For example, such pattern can comprise a series of XOR operations, each performed on a different pair of input variables, and an AND operation performed on every two adjacent XORed pairs of the different pairs of input variables.

Steps of method 200 may either be performed in the order they are presented or in a different order (or even in parallel), as long as the order allows for a necessary input to a certain step to be obtained from an output of an earlier step. In addition, the steps of method 200 are performed automatically (e.g., by computer 101 of FIG. 1, and/or by any other applicable component of computing environment 100), unless specifically stated otherwise.

Method 200 begins in step 202, wherein Boolean circuit evaluator 300 receives a Boolean circuit for evaluation. In some embodiments, the received Boolean circuit comprises a series of conjugation (AND) logical operations of multiple exclusive disjunction (XOR) logical results. For example, a series of XOR operations, each performed on a different pair of input variables, and an AND operation performed on every two adjacent XORed pairs of the different pairs of input variables.

In some embodiments, Boolean circuit evaluator 300 operates within an approximate HE cryptographic scheme environment, such as CKKS, wherein the inputs to the received Boolean circuit must remain encrypted during the circuit evaluation process.

In step 204, the instructions of Boolean circuit analyzer 302 may cause Boolean circuit evaluator 300 to analyze the structure of the received Boolean circuit, to identify a pattern of Boolean operations comprising AND operations of n XOR results, such as the following exemplary pattern over input variable x₁, . . . , x₂ₙ.

$$( {x}_{1} ⊕ {x}_{2} ) ⋀ ( {x}_{3} ⊕ {x}_{4} ) ⋀ … ⋀ ( {x}_{2 n - 1} ⊕ {x}_{2 n} ) .$$

In step 206, the instructions of pseudo-XOR module 304 may cause Boolean circuit evaluator 300 to implement the conjugation (AND) and exclusive disjunction (XOR) logical functions using defined P pseudo logical gates:
A conjugation (AND) pseudo gate denoted herein AND_{P} or ∧_{P}, wherein the input and output values to ∧_{P} are expressed as {−1,0,1} (rather than the standard ‘native’ {0,1}), such that:

$$x {⋀}_{P} y = xy .$$

An exclusive disjunction (XOR) pseudo gate, denoted herein XOR_{P} or ⊕_{P}, wherein the input values to ⊕_{P} are expressed as {0,1}, and the output values to ⊕_{P} are expressed as {−1,0,1}, such that:

$$x {⊕}_{P} y = x - y .$$

Accordingly, in some embodiments, the instructions of pseudo-XOR module 304 may cause Boolean circuit evaluator 300 to implement the following special-purpose pseudo logical gates configured for evaluating Boolean circuits comprising a series of conjugation (AND) logical operations of multiple exclusive disjunction (XOR) logical results:

$$x {⋀}_{P} y = xy , x , y ∈ \{ - 1 , 0 , 1 \}$$

$$x {⊕}_{P} y = ( x - y ) x , y ∈ \{ 0 , 1 \} .$$

In step 208, the instructions of pseudo-XOR module 304 may cause Boolean circuit evaluator 300 to evaluate the Boolean circuit received in step 202 and analyzed in step 204, using the special-purpose pseudo logical gates defined in step 206.

Using the exemplary input pattern detailed in step 204, a standard ‘native’ evaluation (within a computational environment limited to additions and multiplications, such as an approximate HE scheme) of the exemplary pattern of Boolean operations:

$$( {x}_{1} ⊕ {x}_{2} ) ⋀ ( {x}_{3} ⊕ {x}_{4} ) ⋀ … ⋀ ( {x}_{2 n - 1} ⊕ {x}_{2 n} )$$

over an input variable set x₁, . . . , x₂ₙ, may be represented as:

$${( {x}_{1} - {x}_{2} )}^{2} \cdot {( {x}_{3} - {x}_{4} )}^{2} \cdot … \cdot {( {x}_{2 n - 1} - {x}_{2 n} )}^{2} .$$

Accordingly, in some embodiments, the instructions of pseudo-XOR module 304 may cause Boolean circuit evaluator 300 to evaluate the Boolean circuit received in step 202 using the special-purpose pseudo logical gates defined in step 206, wherein the present evaluation replaces each AND operation with its special-purpose pseudo-gate equivalent AND_{P}, and each XOR operation with its special-purpose pseudo-gate equivalent XOR_{P}:

$$x {⋀}_{P} y = xy , x , y ∈ \{ - 1 , 0 , 1 \}$$

$$x {⊕}_{P} y = ( x - y ) x , y ∈ \{ 0 , 1 \} .$$

In some embodiments, the pseudo-gate evaluation may thus be represented as:

$${( ( {x}_{1} {⊕}_{P} {x}_{2} ) {⋀}_{P} ( {x}_{3} {⊕}_{P} {x}_{4} ) {⋀}_{P} … {⋀}_{P} ( {x}_{2 n - 1} {⊕}_{P} {x}_{2 n} ) )}^{2} = {( ( {x}_{1} - {x}_{2} ) \cdot ( {x}_{3} - {x}_{4} ) \cdot … \cdot ( {x}_{2 n - 1} - {x}_{2 n} ) )}^{2} .$$

As can be seen, the present evaluation defers the square operation to the end of the computation, to translate from the {−1,0,1} domain to the {0,1} domain.

The present evaluation result is thus equivalent to the standard ‘native’ evaluation result:

$${( {x}_{1} - {x}_{2} )}^{2} \cdot {( {x}_{3} - {x}_{4} )}^{2} \cdot … \cdot {( {x}_{2 N - 1} - {x}_{2 N} )}^{2} = {( ( {x}_{1} - {x}_{2} ) \cdot ( {x}_{3} - {x}_{4} ) \cdot … \cdot ( {x}_{2 N - 1} - {x}_{2 N} ) )}^{2} ,$$

wherein the number of required square operations is reduced from n to 1, and the total number of multiplications is reduced from n to between n−1 and n/2. Of note, in some cases, a square operation may be considered equivalent to a multiplication, wherein in some HE implementations, a square operation may be performed slightly faster than a standard multiplication.

In step 210, the instructions of output module 308 may cause Boolean circuit evaluator 300 to output the evaluation result calculated in step 208.

The instructions of Boolean circuit evaluator 300 are now discussed with reference to the flowchart of FIG. 2B, which illustrates a method 220 for evaluating a Boolean circuit comprising chains of exclusive disjunction (XOR) operations over 4 input variables x₁, x₂, x₃, x₄, or any multiple of four variables, by recursively repeating the steps of method 220 over two or more groups of four variables within a larger input set. For example, if a received Boolean circuit has a series of 16 variables, they can be divided into four groups of four variables each. The steps of method 220 can be applied to calculate the result of each group of four variables. Then the four output results can be calculated using the steps of method 220, to obtain the calculation result of the entire received circuit.

In some embodiments, method 220 operates within the context of a computational environment that supports only a limited set of arithmetic operation, such as only additions and multiplications over the complex plane.

In some embodiments, the present technique performs this evaluation by leveraging the complex numbers plane to perform a series of XOR operations faster, and by moving back and forth between the complex and real numbers planes. In some embodiments, this solution replaces the required multiplications with the same number of complex conjugate operations, such that for complex number z=a+ib, the conjugate of z is z̅=a−ib, where i=\sqrt{−1} and a, b are real numbers.

Steps of method 220 may either be performed in the order they are presented or in a different order (or even in parallel), as long as the order allows for a necessary input to a certain step to be obtained from an output of an earlier step. In addition, the steps of method 220 are performed automatically (e.g., by computer 101 of FIG. 1, and/or by any other applicable component of computing environment 100), unless specifically stated otherwise.

Method 220 begins in step 222, wherein Boolean circuit evaluator 300 receives a Boolean circuit for evaluation. In some embodiments, the received Boolean circuit comprises a pattern of Boolean operations comprising exclusive disjunction (XOR) over 4 variables x₁, x₂, x₃, x₄.

In some embodiments, Boolean circuit evaluator 300 operates within an approximate HE cryptographic scheme environment, such as CKKS, wherein the inputs to the received Boolean circuit must remain encrypted during the circuit evaluation process.

In step 224, the instructions of Boolean circuit analyzer 302 may cause Boolean circuit evaluator 300 to analyze the structure of the received Boolean circuit, to identify the pattern of Boolean operations comprising exclusive disjunction (XOR) over 4 variables x₁, x₂, x₃, x₄, such as the following exemplary pattern over input variable x₁, . . . , x₄:

$$( {x}_{1} ⊕ {x}_{2} ⊕ {x}_{3} ⊕ {x}_{4} ) .$$

In some embodiments, the present technique is capable of evaluating patterns of Boolean operations comprising more than 4 variables, by dividing the series into groups of four variables.

In step 226, the instructions of complex plane encoder module 306 may cause Boolean circuit evaluator 300 to implement a new encoding of Boolean variables, by converting the inputs from {0,1} to {0,0.5}, as may be needed. Accordingly, in some embodiments, the present technique defines a new encoding of the Boolean variables using x, y∈{0,0.5}, which provide for the following defined T logical gates:
A conjugation (AND) gate denoted herein AND_{T} or ∧_{T}, wherein the input and output values to ∧_{T} are encoded as {0,0.5}, such that:

$$x {⋀}_{T} y = 2 xy ,$$

wherein an additional multiplication operation by a constant (2) is required over the standard ‘native’ AND logical function, to decode the output values to the domain of {0,1}.
A disjunction (OR) gate denoted herein OR_{T} or V_{T}, wherein the input and output values to V_{T} are encoded as {0,0.5}, such that:

$$x {⋁}_{T} y = x + y - 2 xy .$$

An exclusive disjunction (XOR) gate, denoted herein XOR_{T} or ⊕_{T}, wherein the input and output values to ⊕_{T} are expressed as {0,0.5}, such that:

$$x {⊕}_{T} y = 2 {( x - y )}^{2} ,$$

wherein an additional multiplication operation by a constant (2) is required over the standard ‘native’ AND logical function, to decode the output values to the domain of {0,1}.
A negation (NOT) gate, denoted herein NOT_{T} or ¬_{T}, wherein the input and output values to ⊕_{T} are expressed as {0,0.5} such that:

$${¬}_{T} x = 0.5 - x .$$

In step 226, the instructions of complex plane encoder module 306 may cause Boolean circuit evaluator 300 to implement a new encoding of Boolean variables, by converting the input from {0,1} to {0, 0.5}, as may be needed. Accordingly, in some embodiments, the present technique defines a new encoding of the Boolean variables using x, y∈{0,0.5}, which provide for the following defined T logical gates:
A conjugation (AND) gate denoted herein AND_{T} or ∧_{T}, wherein the input and output values to ∧_{T} are encoded as {0,0.5}, such that:

$$x {⋀}_{T} y = 2 xy ,$$

wherein an additional multiplication operation by a constant (2) is required over the standard ‘native’ AND logical function, to decode the output values to the domain of {0,1}.
A disjunction (OR) gate denoted herein ORT or V_{T}, wherein the input and output values to V_{T} are encoded as {0,0.5}, such that:

$$x {⋁}_{T} y = x + y - 2 xy .$$

An exclusive disjunction (XOR) gate, denoted herein XOR_{T} or ⊕_{T}, wherein the input and output values to ⊕r are expressed as {0,0.5}, such that:

$$x {⊕}_{T} y = 2 {( x - y )}^{2} ,$$

wherein an additional multiplication operation by a constant (2) is required over the standard ‘native’ AND logical function, to decode the output values to the domain of {0,1}.
A negation (NOT) gate, denoted herein NOT_{T} or ¬_{T}, wherein the input and output values to ⊕_{T} are expressed as {0,0.5} such that:

$${¬}_{T} x = 0.5 - x .$$

In step 228, the instructions of complex plane encoder module 306 may cause Boolean circuit evaluator 300 to evaluate the Boolean circuit received in step 222 and analyzed in step 224, using the encoding method defined in step 226.

In some embodiments, the present technique performs an addition operation between pairs of consecutive variables, wherein the even-indexed variable in a pair is multiplied by the unit imaginary number i=\sqrt{−1}, such that:

$$A = ( {x}_{1} + {ix}_{2} ) , B = ( {x}_{3} + {ix}_{4} ) .$$

The present technique then performs a standard ‘native’ XOR operation on each pair of the created complex numbers:

$$\begin{matrix}C & = A ⊕ B \\ & = {( ( {x}_{1} + {ix}_{2} ) - ( {x}_{3} + {ix}_{4} ) )}^{2} \\ & = {( ( {x}_{1} - {x}_{3} ) + i ( {x}_{2} - {x}_{4} ) )}^{2} \\ & = {( {x}_{1} - {x}_{3} )}^{2} - {( {x}_{2} - {x}_{4} )}^{2} + 2 i ( {x}_{1} - {x}_{3} ) * ( {x}_{2} - {x}_{4} ) \\ & = \frac{{x}_{1} {⊕}_{T} {x}_{3}}{2} - \frac{{x}_{2} {⊕}_{T} {x}_{4}}{2} + 2 i ( imaginary part ) .\end{matrix}$$

This is because—

$${x}_{1} ⊕ {x}_{3} = {( {x}_{1} - {x}_{3} )}^{2}$$

and

$${x}_{1} {⊕}_{T} {x}_{3} = 2 {( {x}_{1} - {x}_{3} )}^{2}$$

therefore

$$\frac{{x}_{1} {⊕}_{T} {x}_{3}}{2} = {( {x}_{1} - {x}_{3} )}^{2} .$$

The present technique then removes the imaginary part by implementing the T logical gate ⊕_{T} defined in step 226, and using the complex conjugate C̅ of complex number C:

$$D = 2 Re ( C ) = 2 \frac{( C + \overline{C} )}{2} = C + \overline{C} = {x}_{1} {⊕}_{T} {x}_{3} - {x}_{2} {⊕}_{T} {x}_{4} .$$

To complete the operation, the present technique performs:

$$Output = 2 {D}^{2} = {⊕}_{{T}_{\{ i = 1 \}}}^{4} {x}_{i} ,$$

where:
C denotes a complex number.
C̅ denotes the complex conjugate of complex number C.
Re denotes a real number.
D denotes an intermediate real number result.

In step 230, the instructions of output module 308 may cause Boolean circuit evaluator 300 to output the evaluation result calculated in step 228.

In some embodiments, the present technique may combine at least some of the steps of methods 200 and 220, to evaluate an input Boolean circuit comprising a pattern of Boolean operations comprising a series of conjugation (AND) logical operations of multiple exclusive disjunction (XOR) logical results, as well as a pattern of Boolean operations comprising exclusive disjunction (XOR) over 4 variables x₁, x₂, x₃, x₄.

For example, given a Boolean circuit to evaluate, comprising chains of XOR operations over four input variable, with conjugation operations of adjacent XORed pairs. The Boolean circuit may be evaluated using newly defined combined logical gates ∧_{P,T} and ⊕_{P,T}, which combine pseudo logical gates ∧_{P} and ⊕_{P} (described herein below with reference to method 200) with T logical gates ∧_{T} and ⊕_{T} (described herein below with reference to method 220), respectively, to obtain gates ∧_{P,T} and x⊕_{P,T}, wherein:

$$\begin{matrix}x {∧}_{P , T} y = 2 xy , & x , y ∈ \{ - 0.5 , 0 , 0.5 \} \\ x {⊕}_{P , T} y = ( x - y ) , & x , y ∈ \{ 0 , 0.5 \} .\end{matrix}$$

Accordingly, the Boolean circuit may be evaluated by applying newly-defined combined gate ⊕_{P,T} over four variables, and by conjugating the adjacent XORed pairs using ∧_{P,T}.

$$( {⊕}_{P , {T}_{i = 1}^{4}} {x}_{i} ) {∧}_{P , T} ( {⊕}_{P , {T}_{i = 5}^{8}} {x}_{i} ) {∧}_{P , T} . . {∧}_{P , T} ( {⊕}_{P , {T}_{i = 100}^{105}} {x}_{i} ) .$$

This input circuit may be expressed as—

$$( {y}_{1} ) {∧}_{P , T} ( {y}_{2} ) {∧}_{P , T} … {∧}_{P , T} ( {y}_{3} {⊕}_{T} {x}_{105} )$$

wherein

$${y}_{1 , 2} ∈ \{ 0 , 0.5 , - 0.5 \} , {y}_{3} , {x}_{105} ∈ \{ 0 , 0.5 \} ,$$

such that

$$( {y}_{1} ) {∧}_{P , T} ( {y}_{2} ) {∧}_{P , T} . . {∧}_{P , T} ( {y}_{4} ) , \qquad {y}_{1 , 2 , 4} ∈ \{ 0 , 0.5 , - 0.5 \} ,$$

wherein an output result is encoded ∈{0,0.5}, and therefore must be multiplied by a constant (2) to decode the output values to the domain of {0,1}.

Accordingly, the instructions of Boolean circuit evaluator 300 will now be discussed with reference to the flowchart of FIG. 2C, which illustrates a method 240 for evaluating a Boolean circuit comprising chains of XOR operations over four input variables x₁, x₂, x₃, x₄, with conjugation operations of adjacent XORed pairs, within the context of a computational environment that supports only a limited set of arithmetic operation, such as only additions and multiplications. FIG. 3 depicts schematically the process steps of method 240.

Steps of method 240 may either be performed in the order they are presented or in a different order (or even in parallel), as long as the order allows for a necessary input to a certain step to be obtained from an output of an earlier step. In addition, the steps of method 240 are performed automatically (e.g., by computer 101 of FIG. 1, and/or by any other applicable component of computing environment 100), unless specifically stated otherwise.

Method 240 begins in step 242, wherein Boolean circuit evaluator 300 receives a Boolean circuit for evaluation. In some embodiments, the received Boolean circuit comprises a pattern of Boolean operations comprising a series of conjugation (AND) logical operations of multiple exclusive disjunction (XOR) logical results, as well as a pattern of Boolean operations comprising exclusive disjunction (XOR) over 4 variables x₁, x₂, x₃, x₄.

In some embodiments, Boolean circuit evaluator 300 operates within an approximate HE cryptographic scheme environment, such as CKKS, wherein the inputs to the received Boolean circuit must remain encrypted during the circuit evaluation process.

In step 244, the instructions of Boolean circuit analyzer 302 may cause Boolean circuit evaluator 300 to analyze the structure of the received Boolean circuit, to identify the pattern of AND operations of n XOR results within the circuit, such as the following exemplary pattern over input variable x₁, . . . , x₂ₙ.

$$( {x}_{1} ⊕ {x}_{2} ) ∧ ( {x}_{3} ⊕ {x}_{4} ) ∧ … ∧ ( {x}_{2 n - 1} ⊕ {x}_{2 n} ) .$$

In some embodiments, the instructions of Boolean circuit analyzer 302 may further cause Boolean circuit evaluator 300 to analyze the structure of the received Boolean circuit, to identify the pattern of exclusive disjunction (XOR) over 4 variables x₁, x₂, x₃, x₄, such as the following exemplary pattern over input variable x₁, . . . , x₄∈{0,0.5}:

$$( {x}_{1} ⊕ {x}_{2} ⊕ {x}_{3} ⊕ {x}_{4} ) .$$

In some embodiments, the present technique is capable of evaluating patterns of more than 4 variables, by dividing an input series into groups of four variables, and recursively repeating the following steps with respect to each such group. For example, if a received Boolean circuit has a series of 16 variables, they can be divided into four groups of four variables each. The steps of method 240 can be applied to calculate the result of each group of four variables. Then the four output results can be calculated using the steps of method 240, to obtain the calculation result of the entire received circuit.

In step 246, the instructions of pseudo-XOR module 304 may cause Boolean circuit evaluator 300 to implement the conjugation (AND) and exclusive disjunction (XOR) logical functions using defined P pseudo logical gates:
A conjugation (AND) pseudo gate denoted herein AND_{P} or ∧_{P}, wherein the input and output values to ∧_{P} are expressed as {−1,0,1} (rather than the standard ‘native’ {0,1}), such that:

$$x {∧}_{P} y = x y .$$

An exclusive disjunction (XOR) pseudo gate, denoted herein XOR_{P} or ⊕_{P}, wherein the input values to ⊕_{P} are expressed as {0,1}, and the output values to ⊕_{P} are expressed as {−1,0,1}, such that:

$$x {⊕}_{P} y = x - y .$$

Accordingly, in some embodiments, the instructions of pseudo-XOR module 304 may cause Boolean circuit evaluator 300 to implement the following special-purpose pseudo logical gates configured for evaluating Boolean circuits comprising a series of conjugation (AND) logical operations of multiple exclusive disjunction (XOR) logical results:

$$\begin{matrix}x {∧}_{P} y = xy , & x , y ∈ \{ - 1 , 0 , 1 \} \\ x {⊕}_{P} y = ( x - y ) , & x , y ∈ \{ 0 , 1 \} .\end{matrix}$$

In some embodiments, the instructions of complex plane encoder module 306 may further cause Boolean circuit evaluator 300 to implement a new encoding of Boolean variables, by converting the input from {0,1} to {0,0.5}. Accordingly, in some embodiments, the present technique defines a new encoding of the Boolean variables using x, y∈{0,0.5}, which provide for the following defined T logical gates:
A conjugation (AND) gate denoted herein AND_{T} or ∧_{T}, wherein the input and output values to ∧_{T} are encoded as {0,0.5}, such that:

$$x {∧}_{T} y = 2 xy ,$$

wherein an additional multiplication operation by a constant (2) is required over the standard ‘native’ AND logical function, to decode the output values to the domain of {0,1}.
A disjunction (OR) gate denoted herein OR_{T} or r, wherein the input and output values to ∨_{T} are encoded as {0,0.5}, such that:

$${xV}_{T} y = x + y - 2 xy .$$

An exclusive disjunction (XOR) gate, denoted herein XOR_{T} or ⊕_{T}, wherein the input and output values to ⊕_{T} are expressed as {0,0.5}, such that:

$$x {⊕}_{T} y = 2 {( x - y )}^{2} ,$$

wherein an additional multiplication operation by a constant (2) is required over the standard ‘native’ AND logical function, to decode the output values to the domain of {0,1}.
A negation (NOT) gate, denoted herein NOT_{T} or ¬_{T}, wherein the input and output values to ⊕_{T} are expressed as {0,0.5} such that:

$${¬}_{T} x = 0.5 - x .$$

In step 248, the instructions of pseudo-XOR module 304 may cause Boolean circuit evaluator 300 to evaluate the identified patterns of AND operations of n XOR results within the Boolean circuit received in step 242 and analyzed in step 244, using the special-purpose pseudo logical gates defined in step 246, as fully detailed in step 208 of method 200 disclosed hereinabove.

Accordingly, using the exemplary input pattern detailed in step 244, a standard ‘native’ evaluation (within a computational environment limited to additions and multiplications, such as an approximate HE scheme) of the exemplary pattern:

$$( {x}_{1} ⊕ {x}_{2} ) ∧ ( {x}_{3} ⊕ {x}_{4} ) ∧ … ∧ ( {x}_{2 n - 1} ⊕ {x}_{2 n} )$$

over an input variable set x₁, . . . , x₂ₙ, may be represented as:

$${( {x}_{1} - {x}_{2} )}^{2} \cdot {( {x}_{3} - {x}_{4} )}^{2} \cdot … \cdot {( {x}_{2 n - 1} - {x}_{2 n} )}^{2} .$$

Accordingly, in some embodiments, the instructions of pseudo-XOR module 304 may cause Boolean circuit evaluator 300 to evaluate the Boolean circuit received in step 242 using the special-purpose pseudo logical gates defined in step 246, wherein the present evaluation replaces each AND operation with its special-purpose pseudo-gate equivalent AND_{P}, and each XOR operation with its special-purpose pseudo-gate equivalent XOR_{P}:

$$x {∧}_{P} y = x y , x , y ∈ \{ - 1 , 0 , 1 \}$$

$$x {⊕}_{P} y = ( x - y ) x , y ∈ \{ 0 , 1 \} .$$

In some embodiments, the pseudo-gate evaluation may thus be represented as:

$${( ( {x}_{1} {⊕}_{P} {x}_{2} ) {∧}_{P} ( {x}_{3} {XOR}_{P} {x}_{4} ) {∧}_{P} … {∧}_{P} ( {x}_{2 n - 1} {⊕}_{P} {x}_{2 n} ) )}^{2} = {( ( {x}_{1} - {x}_{2} ) \cdot ( {x}_{3} - {x}_{4} ) \cdot … \cdot ( {x}_{2 n - 1} - {x}_{2 n} ) )}^{2} .$$

As can be seen, the present evaluation defers the square operation to the end of the computation, to translate from the {−1,0,1} domain to the {0,1} domain.

In some embodiments, the present evaluation result is thus equivalent to the standard ‘native’ evaluation result:

$${( {x}_{1} - {x}_{2} )}^{2} \cdot {( {x}_{3} - {x}_{4} )}^{2} \cdot … \cdot {( {x}_{2 N - 1} - {x}_{2 N} )}^{2} = {( ( {x}_{1} - {x}_{2} ) \cdot ( {x}_{3} - {x}_{4} ) \cdot … \cdot ( {x}_{2 N - 1} - {x}_{2 N} ) )}^{2} ,$$

wherein the number of required multiplications is reduced from n to n/2, and the number of square operations is reduced from n to 1.

In step 250, the instructions of complex plane encoder module 306 may cause Boolean circuit evaluator 300 to evaluate the identified pattern of exclusive disjunction (XOR) over 4 variables x₁, x₂, x₃, x₄ within the Boolean circuit received in step 242 and analyzed in step 244, using the encoding method defined in step 246, as fully detailed in step 228 of method 220 disclosed hereinabove.

In some embodiments, the present technique performs an addition operation between pairs of consecutive variables, wherein the even-indexed variable in a pair is multiplied by the unit imaginary number i=\sqrt{−1}, such that:

$$A = ( {x}_{1} + i {x}_{2} ) , B = ( {x}_{3} + i {x}_{4} ) .$$

The present technique then performs a standard ‘native’ XOR operation on every pair of complex numbers:

$$C = A ⊕ B = {( ( {x}_{1} + {ix}_{2} ) - ( {x}_{3} + {ix}_{4} ) )}^{2} = {( ( {x}_{1} - {x}_{3} ) + i ( {x}_{2} - {x}_{4} ) )}^{2} = {( {x}_{1} - {x}_{3} )}^{2} - {( {x}_{2} - {x}_{4} )}^{2} + 2 i ( {x}_{1} - {x}_{3} ) * ( {x}_{2} - {x}_{4} ) = \frac{{x}_{1} ⊕ {x}_{3}}{2} - \frac{( {x}_{2} ⊕ {x}_{4} )}{2} + i ( imaginary part ) .$$

The present technique then removes the imaginary part by implementing the T logical gate ⊕_{T} defined in step 246 and using the complex conjugate C̅ of complex number C:

$$D = 2 R e ( C ) = 2 \frac{( C + \overline{C} )}{2} = C + \overline{C} = {x}_{1} {⊕}_{T} {x}_{3} - {x}_{2} {⊕}_{T} {x}_{4} .$$

To complete the operation, the present technique performs:

$$Output = 2 {D}^{2} = {⊕}_{{T}_{\{ i = 1 \}}}^{4} {x}_{i} ,$$

where:
C denotes a complex number.
C̅ denotes the complex conjugate of complex number C.
Re denotes a real number.
D denotes an intermediate real number result.

In step 252, the instructions of output module 308 may cause Boolean circuit evaluator 300 to output the evaluation results calculated in steps 248 and 250.

The instructions of Boolean circuit evaluator 300 will now be discussed with reference to the flowchart of FIG. 2D, which illustrates a method 260 for evaluating a Boolean circuit comprising chains of XOR operations over four input variables x₁, x₂, x₃, x₄, with conjugation operations of adjacent XORed pairs, within the context of a computational environment that supports only a limited set of arithmetic operation, such as only additions and multiplications. FIG. 3 depicts schematically the process steps of method 240.

Steps of method 260 may either be performed in the order they are presented or in a different order (or even in parallel), as long as the order allows for a necessary input to a certain step to be obtained from an output of an earlier step. In addition, the steps of method 260 are performed automatically (e.g., by computer 101 of FIG. 1, and/or by any other applicable component of computing environment 100), unless specifically stated otherwise.

Method 260 begins in step 262, wherein Boolean circuit evaluator 300 receives a Boolean circuit for evaluation. In some embodiments, the received Boolean circuit comprises a pattern of Boolean operations comprising a series of conjugation (AND) logical operations of multiple exclusive disjunction (XOR) logical results, as well as a pattern of Boolean operations comprising exclusive disjunction (XOR) over 4 variables x₁, x₂, x₃, x₄.

In some embodiments, Boolean circuit evaluator 300 operates within an approximate HE cryptographic scheme environment, such as CKKS, wherein the inputs to the received Boolean circuit must remain encrypted during the circuit evaluation process.

In step 264, the instructions of Boolean circuit analyzer 302 may cause Boolean circuit evaluator 300 to analyze the structure of the received Boolean circuit, to identify the pattern of AND operations of n XOR results within the circuit, such as the following exemplary pattern:

$$( ⊕ {x}_{i} ) ∧ ( ⊕ {x}_{i} ) ∧ … ∧ ( ⊕ {x}_{i} ) .$$

Such an exemplary Boolean circuit may comprise a plurality of variables, wherein XOR operations are performed over chains of four variables, and wherein AND operations are performed on adjacent XORed pairs:

$$( {⊕}_{i = 1}^{4} {x}_{i} ) {∧}_{P , T} ( {⊕}_{i = 5}^{8} {x}_{i} ) ∧ … ∧ ( {⊕}_{i = 100}^{105} {x}_{i} ) .$$

In step 266, the received Boolean circuit may be evaluated using newly defined combined logical gates ∧_{P,T} and ⊕_{P,T}, which combine pseudo logical gates ∧_{P} and ⊕_{P} (described herein below with reference to method 200) with T logical gates ∧_{T} and ⊕_{T} (described herein below with reference to method 220), respectively, to obtain gates Λ_{P,T} and x⊕_{P,T}, wherein:

$$x {∧}_{P , T} y = 2 x y , x , y ∈ \{ - 0.5 , 0 , 0.5 \}$$

$$x {⊕}_{P , T} y = ( x - y ) , x , y ∈ \{ 0 , 0.5 \}$$

This input circuit thus may be expressed as—

$$( {⊕}_{P , {T}_{i = 1}}^{4} ) {∧}_{P , T} ( {⊕}_{P , {T}_{i = 5}}^{8} {x}_{i} ) {∧}_{P , T} … {∧}_{P , T} ( {⊕}_{P , {T}_{i = 100}}^{105} {x}_{i} ) = ( {y}_{1} ) {∧}_{P , T} ( {y}_{2} ) {∧}_{P , T} … {∧}_{P , T} ( {y}_{3} {⊕}_{T} {x}_{105} )$$

wherein

$${y}_{1 , 2} ∈ \{ 0 , 0.5 , - 0.5 \} , {y}_{3} , {x}_{105} ∈ \{ 0 , 0.5 \} ,$$

such that

$$( {y}_{1} ) {∧}_{P , T} ( {y}_{2} ) {∧}_{P , T} … {∧}_{P , T} ( {y}_{4} ) , {y}_{1 , 2 , 4} ∈ \{ 0 , 0.5 , - 0.5 \} ,$$

wherein an output result is encoded ∈{0,0.5}, and therefore must be multiplied by a constant (2) to decode the output values to the domain of {0,1}.

In step 268, steps 264 and 266 may be repeated recursively, such that:
(i) step 264 is repeated over a result of the evaluating of step 266, to identify, in the result, a next pattern of Boolean operations comprising one or more sets of XOR operations over four input variable; and
(ii) step 266 is then repeated over the next pattern.

In step 270, at the end of the recursion of step 268, the instructions of output module 308 may cause Boolean circuit evaluator 300 to output the evaluation result calculated in step 268.

### Experimental Results

Table 2 below shows computational of evaluations of various Boolean circuits using the steps of method 220 detailed hereinabove, as compared to the standard ‘native’ evaluation. The result are shown in terms of the total number and type of operations required to complete the evaluation, as well as the difference between the present method and the native implementation.

TABLE 2

| Number of | Number of | | Number of | | Speed Advantage of |
|---|---|---|---|---|---|
| Elements In Input | Operations- | | Operations-Present | | The Present Method |
| Boolean Circuit | Native | | Method | | Difference |
| 4\hat{ }4 = 256 | 255 | sq. | 170 | sq. | 542/400 = 1.355x |
| | | | 85 conj. + mul. by i | | |
| 4\hat{ }5 = 1,024 | 1023 | sq. | 682 | sq. | 1722/1688 = 1.05x |
| | | | 341 conj. + mul. by i | | |
| 4\hat{ }6 = 4,096 | 4095 | sq. | 2730 | sq. | 7304/6251 = 1.16x |
| | | | 1365 conj. + mul. by i | | |
| 4\hat{ }7 = 16,384 | 16,383 | sq. | 10922 | sq. | 29692/26964 = 1.10x |
| | | | 5461 conj. + mul. by i | | |
| 4\hat{ }8 = 65,536 | 65,535 | sq. | 43,690 | sq. | 124655/110576 = 1.12x |

21,845 conj. + mul. by i

Legend:
Squares: Squaring operation.
Conj.: A Conjugate operation in the complex plane.
Mul.: Multiplication operation.
i: The unit imaginary number i = \sqrt{−1}.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

In the description and claims, each of the terms “substantially,” “essentially,” and forms thereof, when describing a numerical value, means up to a 20% deviation (namely, ±20%) from that value. Similarly, when such a term describes a numerical range, it means up to a 20% broader range-10% over that explicit range and 10% below it).

In the description, any given numerical range should be considered to have specifically disclosed all the possible subranges as well as individual numerical values within that range, such that each such subrange and individual numerical value constitutes an embodiment of the invention. This applies regardless of the breadth of the range. For example, description of a range of integers from 1 to 6 should be considered to have specifically disclosed subranges such as from 1 to 3, from 1 to 4, from 1 to 5, from 2 to 4,from 2 to 6, from 3 to 6, etc., as well as individual numbers within that range, for example, 1, 4, and 6. Similarly, description of a range of fractions, for example from 0.6 to 1.1, should be considered to have specifically disclosed subranges such as from 0.6 to 0.9, from 0.7 to 1.1, from 0.9 to 1, from 0.8 to 0.9, from 0.6 to 1.1, from 1 to 1.1 etc., as well as individual numbers within that range, for example 0.7, 1, and 1.1.

The descriptions of the various embodiments of the present invention have been presented for purposes of illustration, but are not intended to be exhaustive or limited to the explicit descriptions. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the description and claims of the application, each of the words “comprise,” “include,” and “have,” as well as forms thereof, are not necessarily limited to members in a list with which the words may be associated.

Where there are inconsistencies between the description and any document incorporated by reference or otherwise relied upon, it is intended that the present description controls.

What is claimed is:

1. A computer-implemented method comprising:
receiving a Boolean circuit embodied in a digital file and input variables associated with the Boolean circuit;
analyzing a structure of said Boolean circuit to identify a pattern of Boolean operations comprising one or more chains of XOR operations over groups of four of the input variables;
automatically evaluating each of said one or more chains of XOR operations over the groups of four input variables, using a defined logical gate XOR_{T} which replaces at least some required multiplication operations with complex conjugate operations; and
automatically calculating any identified AND operations performed on adjacent XORed pairs in said Boolean circuit, using defined pseudo logical gates AND_{P} and XOR_{P}.

2. The computer-implemented method of claim 1, further comprising, recursively:
(i) repeating said analyzing over a result of said evaluating and calculating, to identify, in said result, a next pattern of Boolean operations comprising one or more chains of XOR operations over new groups of four input variables; and
(ii) performing said evaluating and said calculating over said next pattern.

3. The computer-implemented method of claim 2, wherein:
(i) said evaluating is performed, with respect to each of said groups of four input variables, by applying a combined logical gate XOR_{P,T}, such that x XOR_{P,T} y=(x−y), wherein x, y∈{0,0.5}; and
(ii) said calculating is performed, with respect to each adjacent XORed pairs, by applying a combined logical gate AND_{P,T}, such that x AND_{P,T} y=2xy, wherein x, y∈{−0.5,0,0.5}.

4. The computer-implemented method of claim 1, wherein said logical gate XOR is defined such that x XOR_{T} y=2(x−y)², wherein x, y∈{0,0.5}.

5. The computer-implemented method of claim 1, wherein said evaluating is performed by executing an addition operation between pairs of consecutive said input variables, wherein in each of said pairs, an even-indexed variable is multiplied by the unit imaginary number i=\sqrt{−1};

6. The computer-implemented method of claim 1, wherein:
(i) said pseudo logical gate AND _{P} is defined such that x AND_{P} y=xy, wherein x, y∈{−1,0,1}; and
(ii) said pseudo logical gate XOR_{P} is defined such that x XOR_{P} y=(x−y), wherein x, y∈{0,1}.

7. The computer-implemented method of claim 1, wherein said evaluating is performed in a computational environment which supports a limited set of arithmetic operations.

8. The computer-implemented method of claim 7, wherein said limited set of arithmetic operations include additions, multiplications, and conjugations.

9. The computer-implemented method of claim 7, wherein said computational environment is an approximate Homomorphic Encryption (HE) scheme environment, and wherein said input variables and said evaluation results are encrypted.

10. A system comprising:
at least one hardware processor; and
a non-transitory computer-readable storage medium having program code embodied therewith, the program code executable by said at least one hardware processor to:
receive a Boolean circuit embodied in a digital file and input variables associated with the Boolean circuit,
analyze a structure of said Boolean circuit to identify a pattern of Boolean operations comprising one or more chains of XOR operations over groups of four of the input variables,
automatically evaluate each of said one or more chains of XOR operations over the groups of four input variables, using a defined logical gate XOR_{T} which replaces at least some required multiplication operations with complex conjugate operations, and
automatically calculate any identified AND operations performed on adjacent XORed pairs in said Boolean circuit, using defined pseudo logical gates AND_{P} and XOR_{P}.

11. The system of claim 10, wherein said program code is further executable to, recursively:
(i) repeat said analyzing over a result of said evaluating and calculating, to identify, in said result, a next pattern of Boolean operations comprising one or more chains of XOR operations over new groups of four input variables; and
(ii) perform said evaluating and said calculating over said next pattern.

12. The system of claim 11, wherein:
(i) said evaluating is performed, with respect to each of said groups of four input variables, by applying a combined logical gate XOR_{P,T}, such that x XOR_{P,T} y=(x−y), wherein x, y∈{0,0.5}; and
(ii) said calculating is performed, with respect to each adjacent XORed pairs, by applying a combined logical gate AND_{P,T}, such that x AND_{P,T} y=2xy, wherein x, y∈{−0.5,0,0.5}.

13. The system of claim 10, wherein said logical gate XOR is defined such that x XOR_{T} y=2(x−y)², wherein x, y∈{0,0.5}.

14. The system of claim 10, wherein said evaluating is performed by executing an addition operation between pairs of consecutive said input variables, wherein in each of said pairs, an even-indexed variable is multiplied by the unit imaginary number i=\sqrt{−1};

15. The system of claim 10, wherein:
(i) said pseudo logical gate AND_{P} is defined such that x AND_{P} y=xy, wherein x, y∈{−1,0,1}; and
(ii) said pseudo logical gate XOR_{P} is defined such that x XOR_{P} y=(x−y), wherein x, y∈{0,1}.

16. The system of claim 10, wherein said evaluating is performed in a computational environment which supports a limited set of arithmetic operations.

17. The system of claim 16, wherein said limited set of arithmetic operations include additions, multiplications, and conjugations.

18. The system of claim 16, wherein said computational environment is an approximate Homomorphic Encryption (HE) scheme environment, and wherein said input variables and said evaluation results are encrypted.

19. A computer program product comprising a non-transitory computer-readable storage medium having program code embodied therewith, the program code executable by at least one hardware processor to:
receive a Boolean circuit embodied in a digital file and input variables associated with the Boolean circuit;
analyze a structure of said Boolean circuit to identify a pattern of Boolean operations comprising one or more chains of XOR operations over groups of four of the input variables;
automatically evaluate each of said one or more chains of XOR operations over the groups of four input variables, using a defined logical gate XOR_{T} which replaces at least some required multiplication operations with complex conjugate operations; and
automatically calculate any identified AND operations performed on adjacent XORed pairs in said Boolean circuit, using defined pseudo logical gates AND_{P} and XOR_{P}.

20. The computer program product of claim 19, wherein said program code is further executable to, recursively:
(i) repeat said analyzing over a result of said evaluating and calculating, to identify, in said result, a next pattern of Boolean operations comprising one or more chains of XOR operations over new groups of four input variables; and
(ii) perform said evaluating and said calculating over said next pattern.
